(19) United States
(12) Patent Application Publication
(10) Pub. No.: US 2009/0127649 A1
(43) Pub. Date: May 21, 2009

(54) Semiconductor device and method for fabricating the same

(75) Inventor: Akira Uchiyama, Tokyo (JP)

Correspondence Address: RABIN & Berdo, PC, 1101 14TH STREET, NW, SUITE 500, WASHINGTON, DC, 20005, US

(73) Assignee: Oki Semiconductor Co., Ltd., Tokyo (JP)

(21) Appl. No.: 12/292,452

(22) Filed: Nov. 19, 2008

(30) Foreign Application Priority Data
Nov. 20, 2007 (JP) 2007-300247

(51) Int. Cl. H01L 21/762; H01L 29/06

(52) U.S. Cl. 257/506; 438/435; 257/E29.02; 257/E21.546

(57) ABSTRACT

According to the present invention, a semiconductor device includes a semiconductor layer; a device-isolation region formed in the semiconductor layer; an active region surrounded by the device isolation region; and a gap, formed at boundary between the device isolation region and the active region. The gap is not formed under the active region. The gap is formed on a side wall portion of the active region, which extends in a depth direction.

### CROSS REFERENCE TO RELATED APPLICATION

This application claims the priority of Application No. 2007-300247, filed Nov. 20, 2007 in Japan, the subject matter of which is incorporated herein by reference.

### TECHNICAL FIELD OF THE INVENTION

The present invention relates to a semiconductor device and a method for fabricating the same. In particular, the present invention relates to a structure of a MOSFET (Metal-Oxide-Semiconductor Field Effect Transistor) and a method for fabricating the same.

### BACKGROUND OF THE INVENTION

A MOSFET is used in an integrated circuit. A MOSFET using a SOI (Silicon On Insulator) substrate has advantages of lower power consumption and higher operation speed. A MOSFET using a SOI substrate, in which transistors are completely isolated from each other, has a higher radiation resistance. Such a MOSFET has been prospected in a field of space engineering and aeronautical engineering.

FIGS. 1 and 2 show a conventional MOSFET using a SOI structure. FIG. 2 is a cross-sectional view taken on line A-A′ in FIG. 1. In FIGS. 1 and 2, a reference numeral “11” represents a silicon support substrate; and a reference numeral “12” represents a buried oxide layer (SiO2). Device isolation regions 14 and an active region 13 are formed on the oxide layer 12. The active region 13 made of SOI layer is surrounded by the device isolation regions 14. A gate insulating layer 15 and a gate electrode 16 are formed on the active region 13. Although it is not shown in the drawings, a source-drain diffused layer is formed in the active region 13 by an ion implantation process. The diffused layer is located at both sides of the gate electrode 16.

According to the above described conventional MOSFET, a channel of the active region is turned on and off in response to a voltage applied to the gate electrode 16, so that a source-drain current is controlled.

However, according to the conventional MOSFET shown in FIGS. 1 and 2, contact region (boundary region) 21, located between the device isolation regions 14 and the active region (channel) 13, would make a characteristic fluctuation of the transistor. Since sides (outer edge or peripheral) of the active region 13 are in contact with the device isolation layer 14, which is made of silicon oxide layer, an impurity (boron) in the active region 13 may be diffused into the device isolation region 14 during a thermal treatment. As a result, the density of boron in the active region 13 is reduced, and therefore, a threshold value of an N-channel MOSFET would be reduced and leak current would be increased.

Conventionally, boron ions are implanted around the sides (21) of the channel region (boundary). However, boron ions would be diffused toward the inside of the channel region, and therefore, a threshold value at inner portion of the channel would be increased. As a result, driving current is lowered.

In addition, according to the conventional MOSFET shown in FIGS. 1 and 2, characteristics are fluctuated with the passage of time. Pairs of electron and electron hole are formed in oxide layers by radial rays, such as alpha rays. Among those pairs of electron and electron hole, only electron holes with lower mobility are trapped in the oxide layers. Especially, electron holes trapped in the device isolation layer (oxide layer) 14 makes a threshold value at the sides of the channel region lowered, and as a result, a parasitic channel is formed there. If such an undesirable situation has been kept for a long period of time, the device would not operate properly. Boron implantation at the sides of the channel region is one option; however, that is not sufficient in actual operation.

Other conventional inventions are described in publications of JPH01-128442A and JPH05-206257A.

### [Patent Publication 1] JPH01-128442A

### [Patent Publication 2] JPH05-206257A

In patent Publication 1, a semiconductor substrate is provided with a hollow region, in which an oxygen gas is supplied and is heated to form an oxide layer on a surface of the hollow region. A hollow region is formed under an active region.

In patent Publication 2, in order to isolate a silicon region (device region) from the other region of a substrate completely, a hollow region is formed to surround the device region entirely including a region below an active region.

According to patent Publications 1 and 2, a hollow region is formed under (below) an active region. On the other hand, according to the present invention, a gap (hollow region) is only arranged at sides (outer edges or periphery) of an active region under a gate electrode. The present invention is applicable both to a semiconductor device using a SOI substrate, in which an oxide layer is formed under an active region, and to a semiconductor device using a bulk silicon substrate.

According to patent Publication 1, boron ions are implanted into a device region after phosphorus ions are implanted to remain the device region. For that reason, a combination of N+ impurity and P+ impurity may cause a crystal defect, and device characteristics may be deteriorated. On the other hand, according to the present invention, defects in the device region are not increased. Further, according to patent Publication 1, it is required to etch a part under the device region, of which the process is difficult to control. The structure of patent Publication 1 cannot be applied to a semiconductor device using a SOI substrate.

According to patent Publication 2, an epitaxial layer is formed and process costs would be high. On the other hand, according to the present invention, an epitaxial layer is not required. Further, according to patent Publication 2, it is required to etch a part under the device region, of which the process condition is difficult to control. The structure of patent Publication 2 cannot be applied to a semiconductor device using a SOI substrate.

### OBJECTS OF THE INVENTION

Accordingly; an object of the present invention is to provide an improved semiconductor device, in which fluctuation of characteristics can be reduced.

Another object of the present invention is to provide an improved method for fabricating a semiconductor device, in which fluctuation of characteristics can be reduced.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a semiconductor device includes a semiconductor layer; a device-isolation region formed in the semiconductor layer; an active region surrounded by the device isolation region; and a gap, formed at boundary between the device isolation region and the active region. The gap is not formed under the active region. The gap is formed on a side wall portion of the active region, which extends in a depth direction.

According to a second aspect of the present invention, a method for fabricating a semiconductor device according to the first aspect of the present invention, includes the steps of forming a groove in the semiconductor layer by an etching process, to form an active region surrounded by the groove; forming a first insulating layer on the semiconductor layer; etching the first insulating layer to form a side wall layer on a side wall of the active region in a self-align manner; filling a second insulating layer in the groove to form a device isolation region in the semiconductor layer; and removing the side wall layer to form a gap between the active region and device isolation region.

According to a third aspect of the present invention, a method for fabricating a semiconductor device according to the first aspect of the present invention, includes the steps of providing a SOI substrate, including a semiconductor base layer; a substrate insulating layer formed on the semiconductor base layer; and a SOI layer formed on the substrate insulating layer; forming a groove in the SOI layer by an etching process, to form an active region surrounded by the groove, the groove being reached the substrate insulating layer; forming a first insulating layer on the SOI layer; etching the first insulating layer to form a side wall layer on a side wall of the active region in a self-align manner, the side wall layer extending in a depth direction of the SOI layer entirely; filling a second insulating layer in the groove to form a device isolation region in the SOI layer; and removing the side wall layer to form a gap between the active region and device isolation region.

According to a semiconductor device of the first aspect of the present invention, an active region located under a gate electrode is not in contact with device isolation layers, it is prevented that impurity boron is diffused into the device isolation layers. It can be prevented that a density of impurity in the channel region is lowered. As a result, it is unnecessary to implant boron ions into the channel region, and therefore, a threshold value of the active region is prevented from being increased. It can be prevented that driving performance of a MOSFET is lowered.

Even if electron holes (positive holes), generated in the device isolation layers, are trapped at the boundary with sides of the channel region, gaps formed between the channel region (active region) and the device isolation layers prevents undesirable affection of the electron holes to the active region. A specific inductive capacity of the device isolation layers is about 3.9, and that of the gaps (vacuum or void) is 1.0. As compared with the conventional structure of MOSFET, according to the present invention, undesirable affects from electron holes, trapped in the device isolation layers, can be reduced almost one fourth ( 1/3.9).

As described above, according to the present invention, a MOSFET has sufficient driving performance and high reliability of operation.

According to the second aspect of the present invention, side wall layers are formed and removed in a self-aligned process to form gaps. Therefore, an additional mask is not necessary, and narrower gaps can be formed easily independent from lithography performance (accuracy or preciseness).

### BRIEF DESCRIPTION OF THE DRAWINGS

FIG. 1 is a plan view illustrating a conventional semiconductor device.

FIG. 2 is a cross-sectional view taken on line A-A′ in FIG. 1.

FIG. 3 is a plan view illustrating a semiconductor device according to a preferred embodiment of the present invention.

FIG. 4 is a cross-sectional view taken on line B-B′ in FIG. 3.

FIGS. 5A-5H are cross sectional views showing fabrication steps of a semiconductor device according to the preferred embodiment, shown in FIGS. 3 and 4.

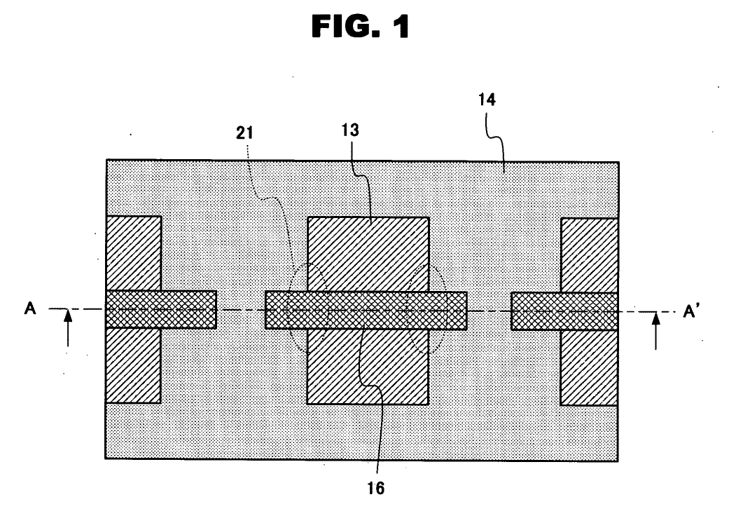

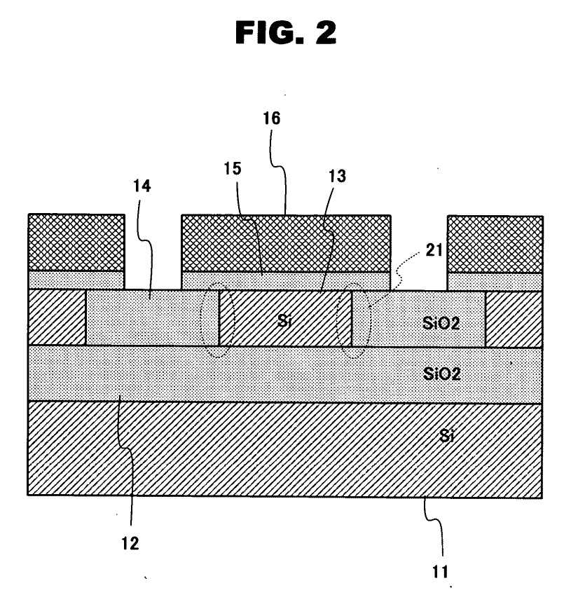

### DESCRIPTION OF REFERENCE NUMERALS

111: Semiconductor Base Layer (Substrate)
112: Buried Oxide Layer
113: Active Region
114: Device Isolation Region
115: Gate Insulating Layer
116: Gate Electrode
117: Gap
127: Side Wall Layer

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

A feature of the present invention is that a gap is formed on boundary between sides of a channel region in an active region and device isolation layers. There is no insulating layer is formed in the gap.

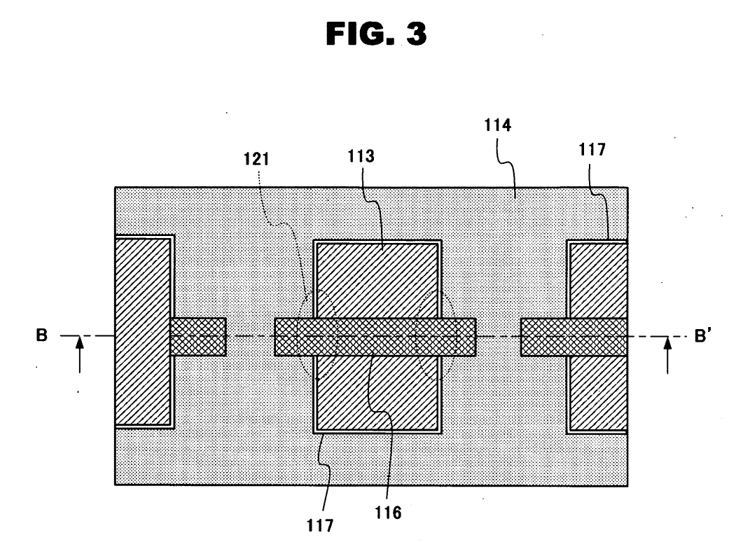

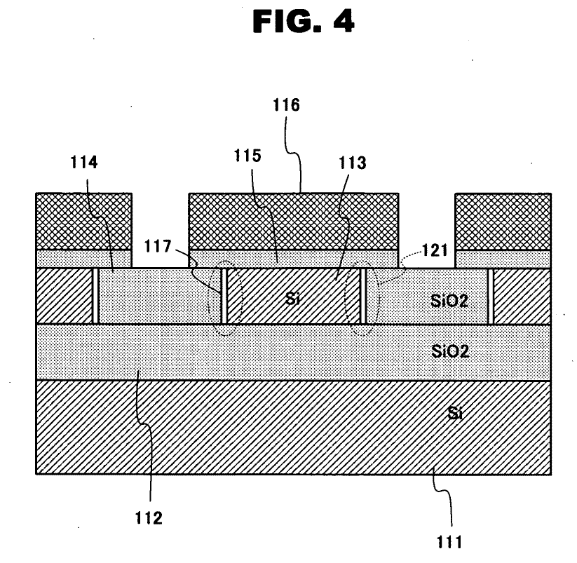

Hereinafter, semiconductor device (MOSFET using a SOI substrate) according to a preferred embodiment of the present invention is described. FIG. 3 is a plan view illustrating a semiconductor device (MOSFET using a SOI substrate) according to a preferred embodiment of the present invention. FIG. 4 is a cross-sectional view taken on line B-B′ in FIG. 3.

A semiconductor device according to the present embodiment, as shown in FIG. 4, includes a P-type silicon support substrate 111; a buried oxide layer 112, formed on the silicon support substrate 111; a device isolation layer 114, formed on the buried oxide layer 112; a P-type silicon active region 113 surrounded by the device isolation layer 114. A gate insulating layer 115 is formed on the active region 113. A gate electrode 116 is formed on the gate insulating layer 115. A gap (void, cavity) 117 is formed on side walls of the active region 113. The gap 117 is not extended under the active region 113.

A feature of the present invention is that the gap 117 is formed at the boundary between the active region 113 and the device isolation layer 114. The gap 117 is formed to have a cross-section width of 50 nm to 200 nm.

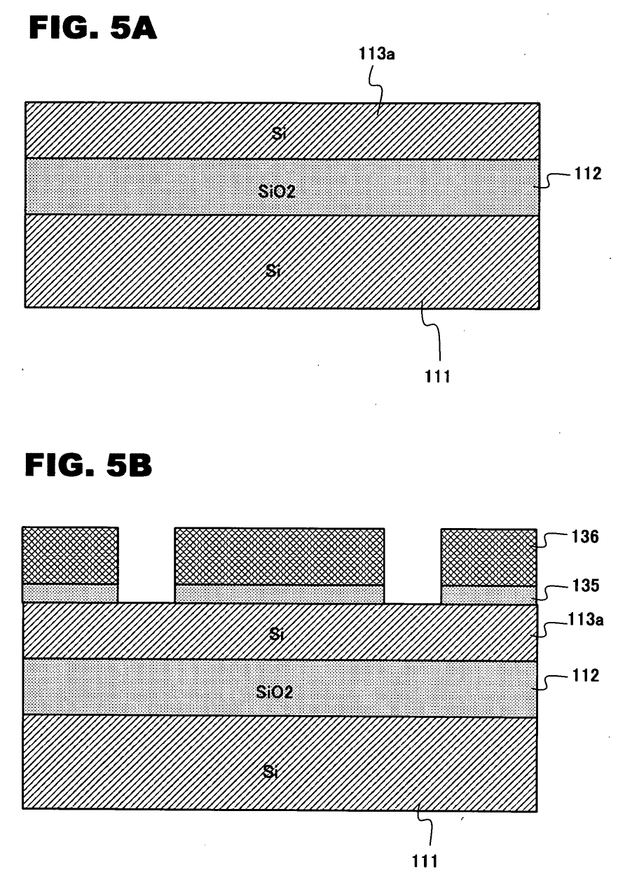

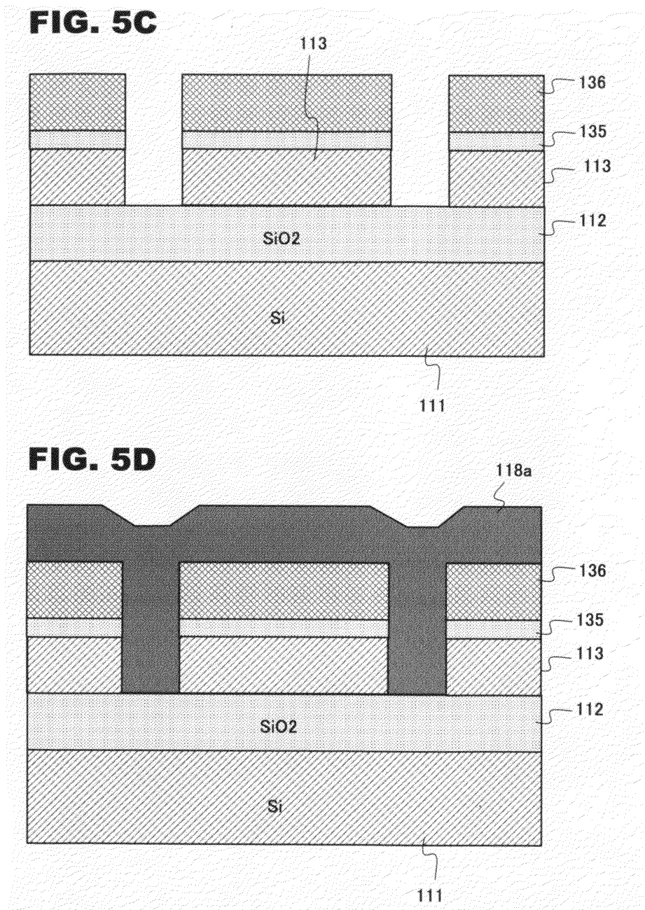

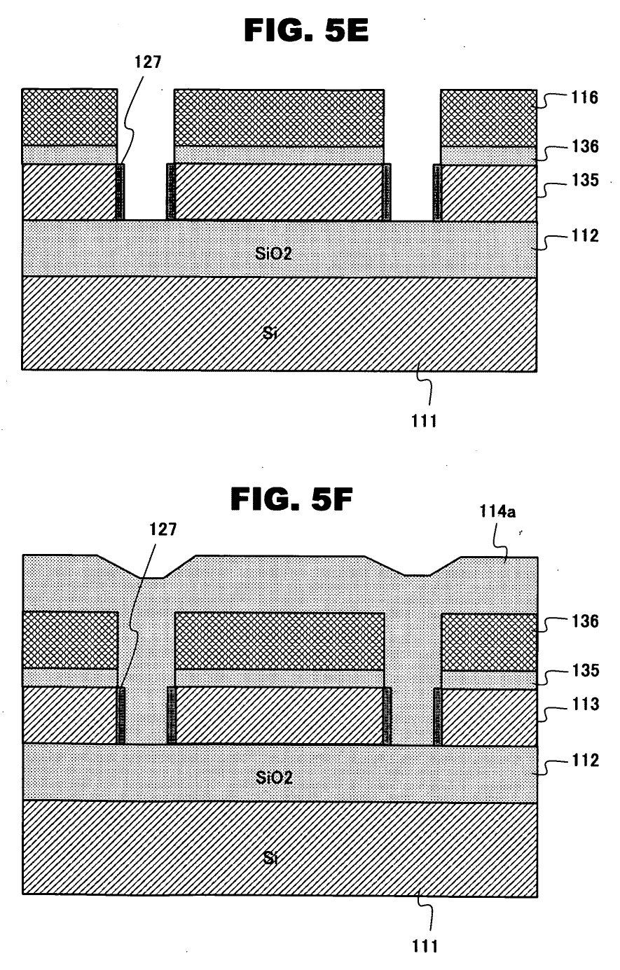

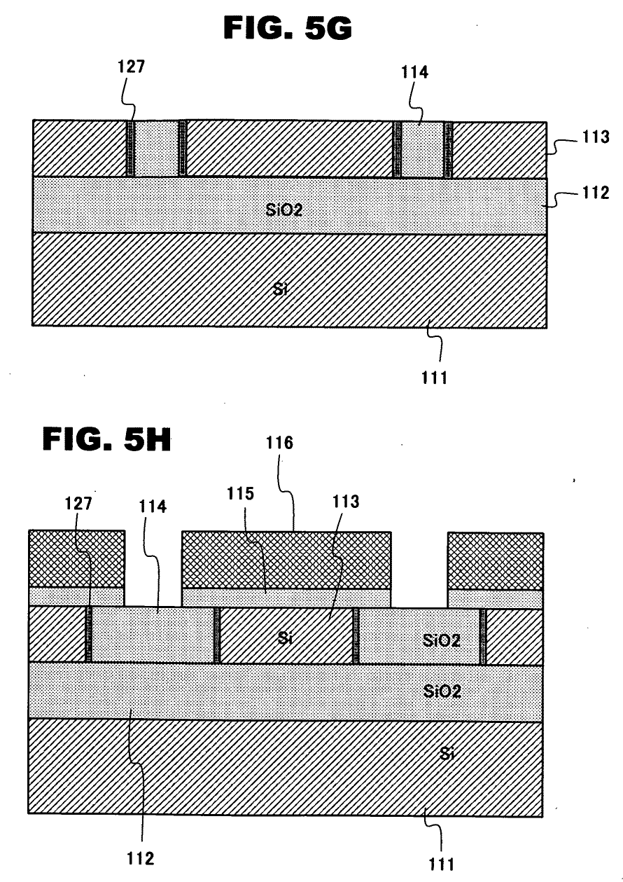

FIGS. 5A to 5H show a part of fabrications steps for the above-described semiconductor device. First, as shown in FIG. 5A, a SOI wafer is prepared. The SOI wafer includes a silicon base substrate 111, a buried oxide layer 112 and a SOI silicon layer 113a. The SOI silicon layer 113a is formed to have a predetermined thickness by an etching process.

Next, as shown FIG. 5B, for example, a silicon oxide layer 135 and a silicon nitride layer 136 are formed on the silicon layer 113a. And then, the silicon oxide layer 135 and silicon nitride layer 136 are patterned to form a mask used for forming an active region. The silicon nitride layer 136 functions as a stopper layer in the following CMP process.

Subsequently, as shown in FIG. 5C, the SOI silicon layer 113a is etched using a mask of the silicon oxide layer 135 and silicon nitride layer 136 to form an active region 113.

Next, as shown in FIG. 5D, a silicon nitride layer 118a is formed on the wafer entirely. After that, as shown in FIG. 5E, side wall layers 127 are formed on inner walls of the active regions in a self-align manner by an anisotropic etching.

Subsequently, as shown in FIG. 5F, a silicon oxide layer 114a is formed on the wafer entirely. After that, the silicon oxide layer 114a and the mask (135 and 136) are polished in a CMP (Chemical Mechanical Polishing) process to form a device isolating layer 114, which is buried, as shown in FIG. 5G. In the CMP process, the silicon nitride layer 136 is used as a stopper for polishing the silicon oxide layer 114a. In other words, such a CMP process is terminated as soon as the silicon nitride layer 136 is exposed.

Next, as shown in FIG. 5H, a gate insulating layer 115 and a gate electrode 116 is formed on the active region 113, and are patterned. After that, the side wall layer 127 is removed by an isotropic etching to form a gap (void, empty region) as shown in FIG. 4. The gate electrode 116 is shaped to have a length of 0.15 um (micro meters) or less, so that the side wall layer 127 located under the gate electrode 116 is sufficiently removed by an isotropic etching process.

For easy understanding of the present invention, an ion implantation process for controlling a threshold value, an ion implantation process for forming a source-drain region, a process for forming a metal wiring, and so on are omitted but are carried out actually in due course.

The MOSFET according to the present invention operates in the same manner as a conventional manner, in which a channel of the active region is turned on and off in response to a voltage applied to the gate electrode 116, so that a source-drain current is controlled.

According to the present embodiment, the active region 113, located under the gate electrode, is not in contact with the device isolation layer 114, so that it can be prevented that boron ions are diffused into the device isolation layer 114 in a thermal treatment. As a result, it can be prevented that the density of impurity in the channel region is lowered. Further, it is not necessary to implant additional boron ions at a boundary between the channel region and the device isolation layer 114, so that the threshold value in the active region is prevented from being increased.

Even if electron holes (positive holes), occurred in the device isolation layer 114, are trapped at the boundary with sides of the channel region, the gap 117 prevents undesirable affection of the electron holes to the active region 113.

A specific inductive capacity of the device isolation layer 114 is about “3.9”, and that of the gap (vacuum or void) 117 is “1.0”. As compared with the conventional structure of MOSFET, according to the present invention, undesirable affects from electron holes, trapped in the device isolation layers, can be reduced almost one fourth ( 1/3.9).

Accordingly, a MOSFET according to the present invention has sufficient driving performance and high reliability of operation.

Further more, according to the present invention, the side wall layer 127 is formed and removed in a self-aligned manner to form the gap 117. Therefore, an additional mask is not necessary, and narrower gaps can be formed easily independent from lithography performance (accuracy or preciseness).

The present invention is applicable not only to a semiconductor device using a SOI substrate, but also applicable to a semiconductor device using a bulk silicon substrate.

In the above described fabrication steps, the order of steps can be changed. For example, the side wall layer 127 can be removed before forming the gate electrode. The side wall layer is formed to have a narrow cross-section area with a width of 50 nm to 200 nm, so that only an upper part of the side wall layer 127 is covered with a layer, formed in a subsequent process. As a result, the gate electrode can be patterned (shaped) properly. In this case, a gap is formed at a location where the side wall layer has been removed from.

According to another alternative method of the present invention, the same steps shown in FIGS. 5A and 5B are carried out, and then, an etching process is carried out to form a gap in the silicon layer 113.

A gap (117) can be formed at a part of side wall region (outer edge) of the active region 113 but not entirely, as shown in FIG. 3. It should be noted that a gap (117) should be formed at least under the gate electrode, as shown in FIG. 4.

What is claimed is:

1. A semiconductor device, comprising:
a semiconductor layer;
a device-isolation region formed in the semiconductor layer;
an active region surrounded by the device isolation region; and
a gap, formed at boundary between the device isolation region and the active region, wherein
the gap is not formed under the active region,
the gap is formed on a side wall portion of the active region, which extends in a depth direction.

2. A semiconductor device according to claim 1, wherein
the gap is formed on the side wall portion of the active region entirely.

3. A semiconductor device according to claim 1, wherein
the gap is formed on a part of the side wall portion of the active region.

4. A semiconductor device according to claim 1, wherein
the semiconductor layer is a SOI layer, which is formed on an insulating layer formed on a semiconductor base layer, and
the active region is formed to have the same thickness as the SOI layer.

5. A method for fabricating a semiconductor device according to claim 1, comprising:
forming a groove in the semiconductor layer by an etching process, to form an active region surrounded by the groove;
forming a first insulating layer on the semiconductor layer;
etching the first insulating layer to form a side wall layer on a side wall of the active region in a self-align manner;
filling a second insulating layer in the groove to form a device isolation region in the semiconductor layer; and
removing the side wall layer to form a gap between the active region and device isolation region.

6. A method according to claim 5, further comprising:
forming a gate electrode on the active region prior to the side wall layer is removed but after the device isolation region is formed.

7. A method according to claim 5, wherein
the side wall layer is removed by an isotropic etching process.

8. A method for fabricating a semiconductor device according to claim 1, comprising:
providing a SOI substrate, including a semiconductor base layer; a substrate insulating layer formed on the semiconductor base layer; and a SOI layer formed on the substrate insulating layer;
forming a groove in the SOI layer by an etching process, to form an active region surrounded by the groove, the groove being reached the substrate insulating layer;
forming a first insulating layer on the SOI layer;
etching the first insulating layer to form a side wall layer on a side wall of the active region in a self-align manner, the side wall layer extending in a depth direction of the SOI layer entirely;
filling a second insulating layer in the groove to form a device isolation region in the SOI layer; and
removing the side wall layer to form a gap between the active region and device isolation region.

9. A method according to claim 8, further comprising:
forming a gate electrode on the active region prior to the side wall layer is removed but after the device isolation region is formed.

10. A method according to claim 8, wherein
the side wall layer is removed by an isotropic etching process.
